(19) United States
(12) Patent Application Publication
(10) Pub. No.: US 2026/0247853 A1
(43) Pub. Date: Aug. 20, 2026

(54) PEROVSKITE COMPOUND AND LIGHT-EMITTING DEVICE INCLUDING THE SAME

(71) Applicant: Foundation of Soongsil University-Industry Cooperation, Seoul (KR)

(72) Inventors: Min Ho PARK, Seoul (KR); Kyoung-Been Shin, Seoul (KR)

(21) Appl. No.: 19/536,636

(22) Filed: Feb. 11, 2026

(30) Foreign Application Priority Data
Feb. 12, 2025 (KR) 10-2025-0018288
Sep. 8, 2025 (KR) 10-2025-0127182

(51) Int. Cl. H10K 85/50; C07F 7/24; C09K 11/06; C09K 111/00; H10K 50/11

(52) U.S. Cl. CPC H10K 85/50; C07F 7/24; C09K 11/06; C09K 2111/00; H10K 50/11

(57) ABSTRACT

A perovskite compound is represented by Formula 1: [Formula 1] ABX₃ wherein A is an inorganic or organic cation, B includes a first ion and one or more metal cations substituting for the first ion, and X is a halogen element.

### CROSS-REFERENCE TO RELATED APPLICATION

This application is based on and claims priority under 35 U.S.C. § 119 to Korean Patent Application N_{0.10}-2025-0018288, filed on Feb. 12, 2025, Korean Patent Application No. 10-2025-0127182, filed on Sep. 8, 2025, the disclosures of which are incorporated by reference herein in their entirety.

### BACKGROUND

### 1. Field

Embodiments of the present disclosure relate to a perovskite compound and a light-emitting device including the same.

This application is the result of research conducted with the support of the Energy Human Resources Development Program (Project No. RS-2024-00398166) of the Ministry of Trade, Industry and Energy (MOTIE), Republic of Korea, managed by the Korea Institute of Energy Technology Evaluation and Planning (KETEP), under the project titled “Graduate School of Energy Policy Convergence (2nd year)” performed by the Soongsil University Industry-Academic Cooperation Foundation for the research period from Jan. 1, 2025 to Dec. 31, 2025, and the Basic Science Research Capacity Building Program (Project No. 2021 R1A6A1A10044154) of the Ministry of Education, Republic of Korea, managed by the National Research Foundation of Korea (NRF), under the project titled “Institute for Convergence of Basic Sciences,” performed by the Soongsil University Industry-Academic Cooperation Foundation for the research period from Mar. 1, 2024 to Feb. 28, 2025.

### 2. Description of the Related Art

A light-emitting device emits light by recombining electrons in a conduction band and holes in a valence band using applied electrical energy, and is used in various fields such as displays, communications, sensors, and energy conversion. A light-emitting device includes an electron injection sublayer, an emission layer, and a hole injection sublayer. Depending on the optical, electrical, and thermal characteristics of the materials used, the device exhibits various features in terms of bandgap tunability, photoluminescence quantum efficiency, charge mobility, and thermal stability.

Meanwhile, perovskite has an ABX₃ structure and may be composed of an A-cation that supports the overall structure, a B-cation that is a transition metal or metal ion located at the center of the structure, and an X-anion that surrounds the B-cation to form an octahedron. Perovskite has attracted attention for use in light-emitting devices due to its excellent light absorption characteristics and high emission efficiency, and development of perovskite light-emitting devices has been actively pursued.

### SUMMARY

Embodiments of the present disclosure provide a compound having a multi-component perovskite structure with improved optical and structural stability, and a light-emitting device including the compound.

According to an embodiment of the present disclosure, there is provided a perovskite compound represented by [Formula 1] ABX₃ wherein, in Formula 1, A is an inorganic or organic cation, B includes a first ion and one or more metal cations substituting for the first ion, and X is a halogen element.

In the present embodiment, A may be FA, FA(CH(NH₂)₂), MA(CH₃NH₃), or Cs.

In the present embodiment, X may be I, Br, or Cl.

In the present embodiment, the first ion may be Pb, and B may be represented by Formula 2.

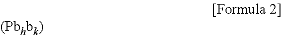

b is an element selected from Cd, Zn, Mg, Ni, Sr, Sn, Ca, Mn, and Ge, and h+k=1.

In the present embodiment, the first ion may be Pb, and B may be represented by Formula 3.

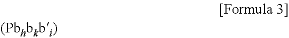

Each of b and b′ is an element selected from Cd, Zn, Mg, Ni, Sr, Sn, Ca, Mn, and Ge, and h+k+i=1.

In the present embodiment, the first ion may be Pb, and B may be represented by Formula 4.

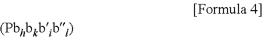

Each of b, b′, and b″ is an element selected from Cd, Zn, Mg, Ni, Sr, Sn, Ca, Mn, and Ge, and h+k+i+I=1.

In the present embodiment, A may be represented by Formula 5.

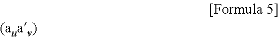

Each of a and a′ is selected from FA, FA(CH(NH₂)₂), MA(CH₃NH₃), or Cs, and u+v=1.

In the present embodiment, A may be represented by Formula 6.

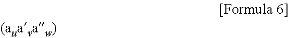

Each of a, a′, and a″ is selected from FA, FA(CH(NH₂)₂), MA(CH₃NH₃), or Cs, and u+v+w=1.

In the present embodiment, X may be represented by Formula 7.

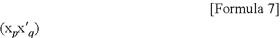

Each of x and x′ is selected from I, Br, or Cl, and p+q=3.

In the present embodiment, X may be represented by Formula 8.

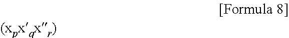

Each of x, x′, and x″ is selected from I, Br, or Cl, and p+q+r=3.

According to another embodiment of the present disclosure, there is provided a light-emitting device including: a substrate; a hole transport layer on the substrate; an emission layer on the hole transport layer; an electron transport layer on the emission layer; and a cathode on the electron transport layer, wherein the emission layer includes the perovskite compound according to claim 1.

Other aspects, features, and advantages other than those described above will become apparent from the following drawings, claims, and detailed description of the disclosure.

### BRIEF DESCRIPTION OF THE DRAWINGS

FIG. 1 is a view illustrating emission colors of perovskite nanoparticles.

FIG. 2 is a view illustrating optical bandgaps of perovskite nanoparticles.

FIG. 3 is a view illustrating X-ray diffraction (XRD) analysis results of perovskite nanoparticles.

FIG. 4 is a scanning electron microscope (SEM) image of a perovskite nanoparticle thin film.

FIG. 5 is a view illustrating thermogravimetry of perovskite nanoparticles.

FIG. 6 is a view illustrating photoluminescence intensity of perovskite nanoparticles.

FIG. 7 is a view illustrating performance of a perovskite light-emitting device based on perovskite nanoparticles.

### DETAILED DESCRIPTION

Since the present disclosure may be embodied in many different forms and may have various modifications, specific embodiments are illustrated in the drawings and described in detail in the following detailed description. The effects and features of the present disclosure, and methods of achieving the same, will become apparent by reference to the embodiments described in detail below in conjunction with the accompanying drawings. However, the present disclosure is not limited to the embodiments disclosed hereinafter and may be embodied in various forms.

Hereinafter, embodiments of the present disclosure will be described in detail with reference to the accompanying drawings. In the following description with reference to the drawings, like reference numerals denote like or corresponding elements, and redundant descriptions thereof will be omitted.

In the following embodiments, the terms “first,” “second,” and the like are used not in a limiting sense but for the purpose of distinguishing one element from another.

In the following embodiments, singular expressions include plural expressions unless the context clearly indicates otherwise.

In the following embodiments, terms such as “comprise” or “have” are intended to designate that a feature or element described in the specification is present, and do not preclude the possibility that one or more other features or elements may be added.

In the drawings, sizes of elements may be exaggerated or reduced for convenience of description. For example, the size and thickness of each element shown in the drawings are arbitrarily illustrated for convenience of description, and thus the present disclosure is not necessarily limited to what is illustrated.

In the following embodiments, the x-axis, y-axis, and z-axis are not limited to three axes of a Cartesian coordinate system and may be interpreted in a broader sense including the same. For example, the x-axis, y-axis, and z-axis may be orthogonal to one another, but may also refer to different directions that are not orthogonal to one another.

Where a particular embodiment may be implemented differently, a specific process order may be performed differently from the order described. For example, two processes described in succession may be performed substantially simultaneously, or may be performed in an order reverse to the order described.

A compound of the present disclosure may include a perovskite structure of ABX₃. A may be an organic or inorganic monovalent cation, and for example, may be FA, FA(CH(NH₂)₂), MA(CH₃NH₃), or Cs. X may be a halogen anion, and for example, may be I, Br, or Cl.

As an embodiment, A may have a structure of (aᵤa′ᵥ) or (aᵤa′ᵥa″_{w}), and each of a, a′, and a″ may be FA, FA(CH(NH₂)₂), MA(CH₃NH₃), or Cs. u, v, and w may be mole fractions of a, a′, and a″, respectively; for example, in the case of (aᵤa′ᵥ)BX₃, 0<u<1, 0<v<1, and u+v=1 may be satisfied, and in the case of (aᵤa′ᵥa″_{w})BX₃, 0<u<1, 0<v<1, 0<w<1, and u+v+w=1 may be satisfied.

As an embodiment, X may have a structure of (xₚx′_{q}) or (xₚx′_{q}x″ᵣ), and each of x, x′, and x″ may be I, Br, or Cl. p, q, and r may be mole fractions of x, x′, and x″, respectively; for example, in the case of AB(xₚx′_{q}), 0<p<3, 0<q<3, and p+q=3 may be satisfied, and in the case of AB(xₚx′_{q}x″ᵣ), 0<p<3, 0<q<3, 0<r<3, and p+q+r=3 may be satisfied.

B may include a first ion and one or more metal cations substituting for a portion of the first ion, and for example, the first ion may be Pb. Hereinafter, FAPbBr₃ will be described as an example.

Nanoparticles having different numbers of B-site cation species may be synthesized by partially substituting Pb²⁺ ions of FAPbBr₃ nanoparticles. Specifically, Pb²⁺ ions may be substituted with metal cations such as Cd²⁺, Zn²⁺, Mg²⁺, and Ni²⁺, and multi-component perovskite nanoparticles may be synthesized therefrom. The cation-substituted nanoparticles may be multi-component perovskite nanoparticles having high structural disorder and various cation combinations.

The cation-substituted nanoparticles may have structures of FA(Pbₕbₖ)Br₃, FA(Pbₕbₖb′ᵢ)Br₃, or FA(Pbₕbₖb′ᵢb″ᵢ)Br₃ by partially substituting Pb, which is the B-site cation, and each of b, b′, and b″ may be Cd, Zn, Mg, Ni, Sr, Sn, Ca, Mn, or Ge. h, k, i, and I may be mole fractions of Pb, b, b′, and b″, respectively; for FA(Pbₕbₖ)Br₃, h+k=1 may be satisfied, for FA(Pbₕbₖb′ᵢ)Br₃, h+k+i=1 may be satisfied, and for FA(Pbₕbₖb′ᵢb″ᵢ)Br₃, h+k+i+1=1 may be satisfied.

For example, for FA(Pbₕbₖ)Br₃, 0.5≤h<1 and 0<k≤0.5 may be satisfied; for FA(Pbₕbₖb′ᵢ)Br₃, 0.33≤h<1, 0<k≤0.33, and 0<i≤0.33 may be satisfied; and for FA(Pbₕbₖb′ᵢb″I)Br₃, 0.25≤h<1, 0<k≤0.25, 0<i≤0.25, and 0<I≤0.25 may be satisfied.

As an embodiment, two or more types of ions may be doped into each of the A-site, B-site, or X-site of the perovskite compound. The ions at each site may be multi-elemental, and for example, the B-site may have two or three constituent element species. A perovskite compound including multiple elements may exhibit increased entropy, and when applied to a light-emitting device, optical uniformity and device lifespan may be improved.

As another example, each of the A-site and the B-site may have two constituent element species, and as yet another example, the B-site may have four or more constituent element species. In the multi-component perovskite compound, a single phase may be stabilized by a high-entropy effect, and the thermal and chemical stability of a crystal structure may be improved.

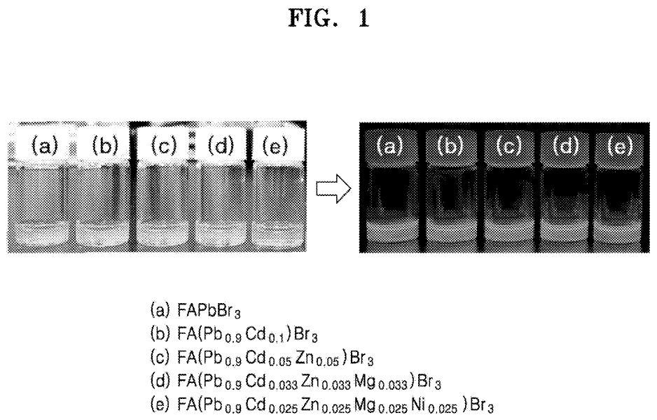

FIG. 1 is a view illustrating emission colors of perovskite nanoparticles.

Referring to FIG. 1, for each of the perovskite nanoparticles, no change in emission color was observed when irradiated with ultraviolet light at a wavelength of 365 nm, and the photoluminescence wavelength range remained the same before and after substitution. These results confirm that cation partial substitution does not affect emission energy levels. The cation-substituted nanoparticles, namely FA(Pb_{0.9}Cd_{0.1})Br₃, FA(Pb_{0.9}Cd_{0.05}Zn_{0.05})Br₃, FA(Pb_{0.9}Cd_{0.033}Zn_{0.033}Mg_{0.033})Br₃, and FA(Pb_{0.9}Cd_{0.025}Zn_{0.025}Mg_{0.025}Ni_{0.025})Br₃, and the nanoparticles before substitution, namely FAPbBr₃, exhibited negligible change in bandgap; thus, the optical function and normal crystalline state of the material may be maintained even after B-site partial substitution. Accordingly, a light-emitting device to which the cation-substituted nanoparticles are applied may maintain uniform optical performance, for example, emission color. As an example, a light-emitting device may include a substrate, a hole transport layer, an emission layer, an electron transport layer, and a metal cathode, wherein the hole transport layer may include a hole injection sublayer and a hole transport sublayer, and the electron transport layer may include an electron transport sublayer and an electron injection sublayer. The emission layer may be a perovskite nanocrystal layer to which cation-substituted nanoparticles are applied, and the emission layer may emit at a consistent wavelength, thereby enabling a uniform and highly reliable device.

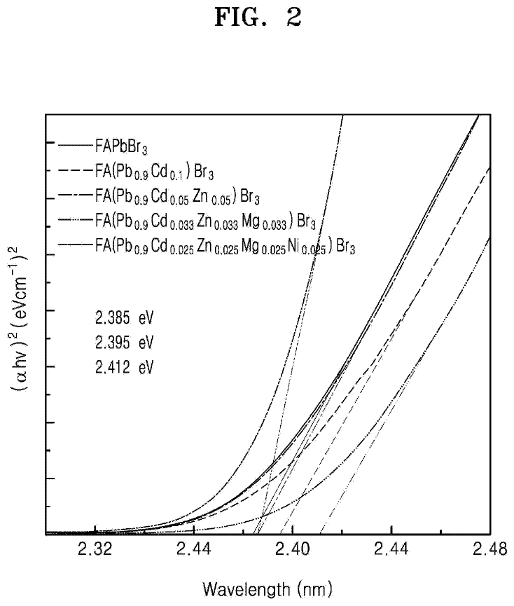

FIG. 2 is a view illustrating optical bandgaps of perovskite nanoparticles.

Referring to FIG. 2, absorbance of each of the perovskite nanoparticles was measured, and optical bandgaps were calculated using absorption coefficients and photon energy. The bandgap of FAPbBr₃ nanoparticles was 2.385 eV, and FA(Pb_{0.9}Cd_{0.05}Zn_{0.05})Br₃ nanoparticles and FA(Pb_{0.9}Cd_{0.025}Zn_{0.025}Mg_{0.025}Ni_{0.025})Br₃ nanoparticles had similar values thereto, while FA(Pb_{0.9}Cd_{0.1})Br₃ nanoparticles had a bandgap of 2.395 eV and FA(Pb_{0.9}Cd_{0.033}Zn_{0.033}Mg_{0.033})Br₃ nanoparticles had a bandgap of 2.412 eV, which confirms that there is almost no change in the bandgap. These results confirm that metal cation substitution does not affect electron transition energy and that the band structure of the perovskite nanoparticles is stably maintained. Accordingly, a light-emitting device to which the perovskite nanoparticles are applied may maintain uniform emission characteristics and an emission wavelength even during long-term operation, and a light-emitting device having high stability and high reliability may be manufactured.

Table 1 below shows quantum efficiency of the perovskite nanoparticles.

TABLE 1

| | Quantum |
|---|---|
| Perovskite nanoparticles | efficiency (%) |
| FAPbBr₃ | 65.50 |
| FA(Pb_{0.9}Cd_{0.1})Br₃ | 66.00 |
| FA(Pb_{0.9}Cd_{0.05}Zn_{0.05})Br₃ | 68.93 |
| FA(Pb_{0.9}Cd_{0.033}Zn_{0.033}Mg_{0.033})Br₃ | 68.98 |
| FA(Pb_{0.9}Cd_{0.025}Zn_{0.025}Mg_{0.025}Ni_{0.025})Br₃ | 60.54 |

Table 1 shows photoluminescence quantum efficiency of perovskite nanoparticles for various ion compositions. The quantum efficiency of FAPbBr₃ nanoparticles was measured as 65.50%, the quantum efficiency of FA(Pb_{0.9}Cd_{0.1})Br₃ nanoparticles was measured as 66.00%, the quantum efficiency of FA(Pb_{0.9}Cd_{0.05}Zn_{0.05})Br₃ nanoparticles was measured as 68.93%, and the quantum efficiency of FA(Pb_{0.9}Cd_{0.033}Zn_{0.033}Mg_{0.033})Br₃ nanoparticles was measured as 68.98%. For substitution with Cd²⁺, Zn²⁺, and Mg²⁺, photoluminescence quantum efficiency increased as the number of B-site cation species increased. These results confirm that cation substitution alters the environment around emission centers, thereby suppressing non-radiative recombination and improving emission efficiency. Through co-introduction of various metal cations, defects within the lattice may be dispersed, suppressing non-radiative recombination pathways and thereby increasing the radiative recombination ratio. An increase in quantum efficiency may increase device efficiency and luminance of a light-emitting device, and may provide high luminance and a long lifespan even at a low driving voltage. Accordingly, the light-emitting material may minimize recombination loss and improve device stability and lifespan, and a high-efficiency light-emitting device may be manufactured by applying cation-substituted nanoparticles.

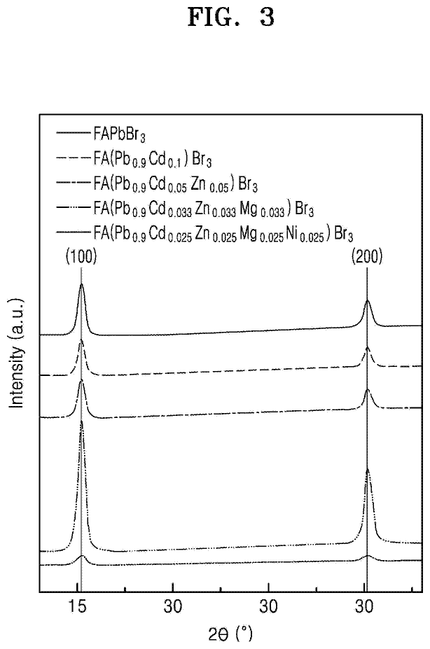

FIG. 3 is a view illustrating X-ray diffraction (XRD) analysis results of perovskite nanoparticles.

Referring to FIG. 3, the crystal structure was analyzed using the XRD pattern of FAPbBr₃ nanoparticles, and specifically, the crystal structure following partial cation substitution was analyzed by preparing FAPbBr₃ nanoparticle thin films with controlled compositions and measuring the XRD patterns thereof. The (100) peak and (200) peak of the nanoparticles were observed at about 15° and about 30°, respectively, and the observation that main diffraction peaks in the XRD pattern appear at the same 2θ positions before and after substitution confirms that the crystal structure is maintained. Specifically, lattice constants are maintained even after metal cations such as Cd²⁺, Zn²⁺, and Mg²⁺ partially substitute for B-site Pb²⁺, so that the basic crystal structure of FAPbBr₃ may be stably maintained. The substituted ions have ionic radii similar to those of Pb²⁺, which is the original B-site ion, such that the substitution may remain fine or locally dispersed, and deformation of the crystal structure may not occur. Accordingly, the B-site cation-substituted nanoparticles may improve material performance, for example, photoelectric characteristics, bandgap, and thermal stability, without collapse of the crystal structure, and a light-emitting device having improved performance and lifespan may be manufactured.

Table 2 below shows (100) peak intensity and crystallite size of perovskite nanoparticles, and Table 3 shows ionic radii of B-site cations.

TABLE 2

| | (100) Peak | Crystallite |
|---|---|---|
| Perovskite nanoparticles | intensity | size (nm) |
| FAPbBr₃ | 2235 | 20.70 |
| FA(Pb_{0.9}Cd_{0.1})Br₃ | 1611 | 20.44 |
| FA(Pb_{0.9}Cd_{0.05}Zn_{0.05})Br₃ | 1705 | 20.56 |
| FA(Pb_{0.9}Cd_{0.033}Zn_{0.033}Mg_{0.033})Br₃ | 3659 | 21.03 |
| FA(Pb_{0.9}Cd_{0.025}Zn_{0.025}Mg_{0.025}Ni_{0.025})Br₃ | 494 | 14.12 |

TABLE 3

| B-site cations | Ionic radius (Å) |
|---|---|
| Pb²⁺ | 1.2 |
| Cd²⁺ | 0.95 |
| Zn²⁺ | 0.74 |
| Mg²⁺ | 0.72 |
| Ni²⁺ | 0.69 |

The (100) peak intensity of FA(Pb_{0.9}Cd_{0.1})Br₃ nanoparticles was measured as 1611, the (100) peak intensity of FA(Pb_{0.9}Cd_{0.05}Zn_{0.05})Br₃ nanoparticles was measured as 1705, and the (100) peak intensity of FA(Pb_{0.9}Cd_{0.033}Zn_{0.033}Mg_{0.033})Br₃ nanoparticles was measured as 3659. Peak intensity increased as Cd²⁺, Zn²⁺, and Mg²⁺ were successively introduced, confirming that crystallinity was improved without changes in the crystal structure. An increase in peak intensity may be attributed to an increase in crystallite size or a decrease in defect density within the crystal, either of which may facilitate smooth charge transport. High crystallinity may improve charge mobility, thereby increasing the lifetime or efficiency of photocarriers in a photoelectric device or a light-emitting device. Cation partial substitution may promote a more uniform arrangement of nanoparticles, thereby reducing internal defects, and accordingly, may improve the stability and crystallinity of the crystal structure of the light-emitting material.

Upon introduction of Cd²⁺ and Zn²⁺ having ionic radii similar to that of Pb²⁺, excessive lattice contraction or distortion due to substitution within the lattice may be minimized, and degradation of structural stability and emission characteristics caused by perovskite lattice changes may be prevented. For example, the B-site elemental components of the compound may be PbCdZn, PbCdMg, PbZnMg, PbCdZnMg, PbCdZnNi, or the like; and by substituting with ions of similar sizes, stress due to lattice imbalance is not induced, thereby allowing the light-emitting material to stably maintain optical characteristics.

As a result of cation substitution, the crystallite size decreased when Cd²⁺ was doped, the crystallite size subsequently increased after Zn²⁺ and Mg²⁺ were doped, and the crystallite size decreased sharply when Ni²⁺ was doped. Changes in crystallite size may depend on multiple factors such as nucleation and growth rates, defect density, and stress, and B-site cation doping may affect nucleation density and defect density. For example, upon substitution with an ion having a relatively large ionic radius such as Cd²⁺, crystal growth may be inhibited such that crystallite size may decrease; upon substitution with ions having small ionic radii such as Zn²⁺ and Mg²⁺, crystal growth may be promoted such that crystallite size may increase; and an ion such as Ni²⁺ may sharply interfere with crystal growth such that crystallite size may be significantly reduced. Cation partial substitution may reduce grain boundary density, and thus may improve charge mobility and reduce optical loss of the light-emitting material.

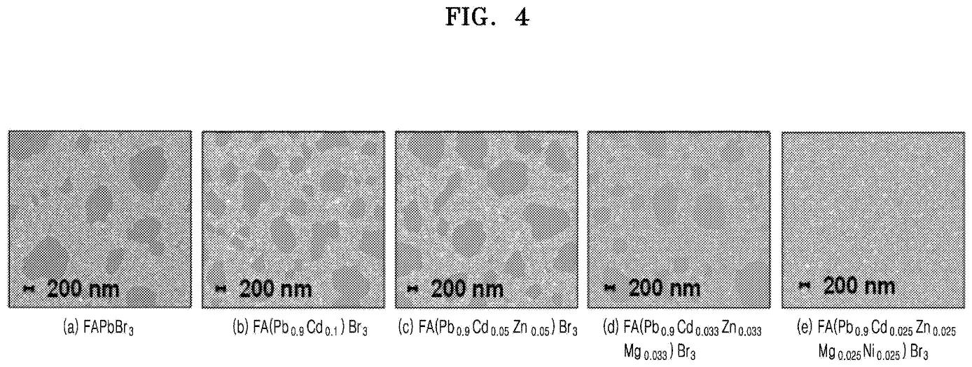

FIG. 4 is an SEM image of a perovskite nanoparticle thin film.

Referring to FIG. 4, the thin film surface morphology and the presence or absence of defects in the cation-substituted nanoparticle films may be observed. The SEM images show that the FA(Pb_{0.9}Cd_{0.025}Zn_{0.025}Mg_{0.025}Ni_{0.025})Br₃ nanoparticle thin film having five B-site ion species has almost no pinholes and exhibits the highest surface uniformity. Cation partial substitution may improve the electrical and optical performance of the material by reducing defects and non-uniformity within the thin film, and accordingly, by introducing various B-site cations, the surface quality of the thin film may be improved, thereby forming a uniform surface structure.

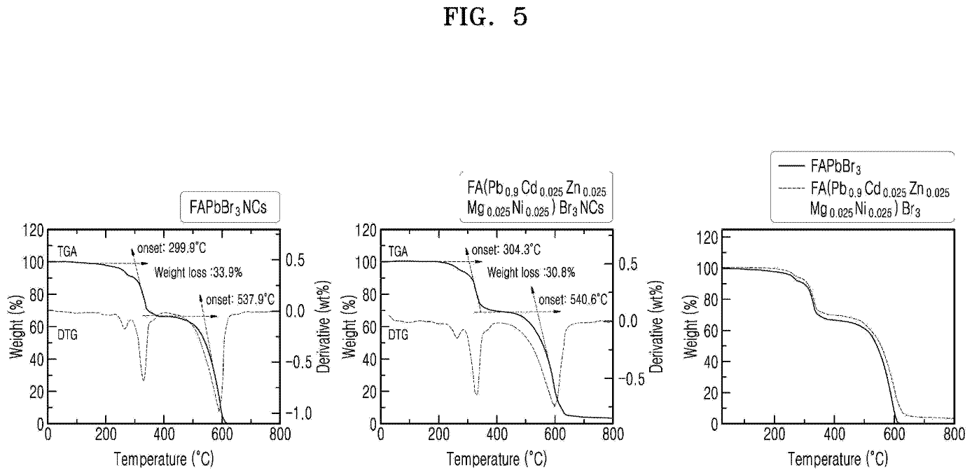

FIG. 5 is a view illustrating thermogravimetry of perovskite nanoparticles.

Referring to FIG. 5, thermogravimetry was analyzed by measuring mass changes upon heating of FAPbBr₃ nanoparticles and FA(Pb_{0.9}Cd_{0.025}Zn_{0.025}Mg_{0.025}Ni_{0.025})Br₃ nanoparticles. The decomposition onset temperatures of the FAPbBr₃ nanoparticles were measured as 299.9° C. and 537.9° C., and those of the FA(Pb_{0.9}Cd_{0.025}Zn_{0.025}Mg_{0.025}Ni_{0.025})Br₃ nanoparticles were measured as 304.3° C. and 540.6° C. The mass loss of the FAPbBr₃ nanoparticles was measured as 33.9%, and the mass loss of the FA(Pb_{0.9}Cd_{0.025}Zn_{0.025}Mg_{0.025}Ni_{0.025})Br₃ nanoparticles was measured as 30.8%.

The cation-substituted nanoparticles exhibited a slightly higher decomposition onset temperature than the FAPbBr₃ nanoparticles, and reduced overall mass loss. The cation-substituted nanoparticles may have improved thermal stability compared to conventional nanoparticles, and B-site ion substitution may increase thermal decomposition resistance, stably maintaining the crystal structure and physical properties at higher temperatures.

Thin films formed using the cation-substituted nanoparticles or light-emitting devices including the same may maintain structural stability even in high-temperature processes or operating environments, and material decomposition or performance degradation may be reduced. Accordingly, the cation-substituted nanoparticles may achieve excellent thermal stability and durability even in a high-temperature environment, and stable and highly reliable devices may be manufactured.

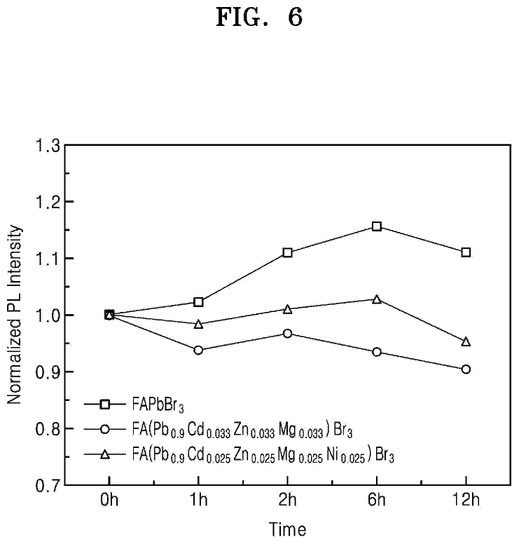

FIG. 6 is a view illustrating photoluminescence intensity of perovskite nanoparticles.

Referring to FIG. 6, FAPbBr₃ nanoparticles and multi-component perovskite nanoparticles were formed into thin films, and changes in photoluminescence intensity over time were normalized and illustrated.

The FAPbBr₃ nanoparticles showed a pattern in which light scattering decreased and light extraction efficiency increased as aggregation between particles progressed. The FA(Pb_{0.9}Cd_{0.033}Zn_{0.033}Mg_{0.033})Br₃ nanoparticles and FA(Pb_{0.9}Cd_{0.025}Zn_{0.025}Mg_{0.025}Ni_{0.025})Br₃ nanoparticles showed a pattern in which the magnitude of increase in photoluminescence intensity was small and the overall change was small due to reduced aggregation. These results confirm that, for the cation-substituted perovskite nanoparticles, lattice distortion was suppressed and surface energy was reduced due to the high-entropy effect, thereby preventing aggregation between particles. The cation-substituted nanoparticles may exhibit improved light output stability, particularly room temperature stability, through lattice stabilization, and optical distortion may be reduced. As color distortion due to scattering or reflection is reduced, the light-emitting material may enable precise control of emission color, and accordingly, a highly reliable light-emitting device may be realized by consistently maintaining emission efficiency and color quality.

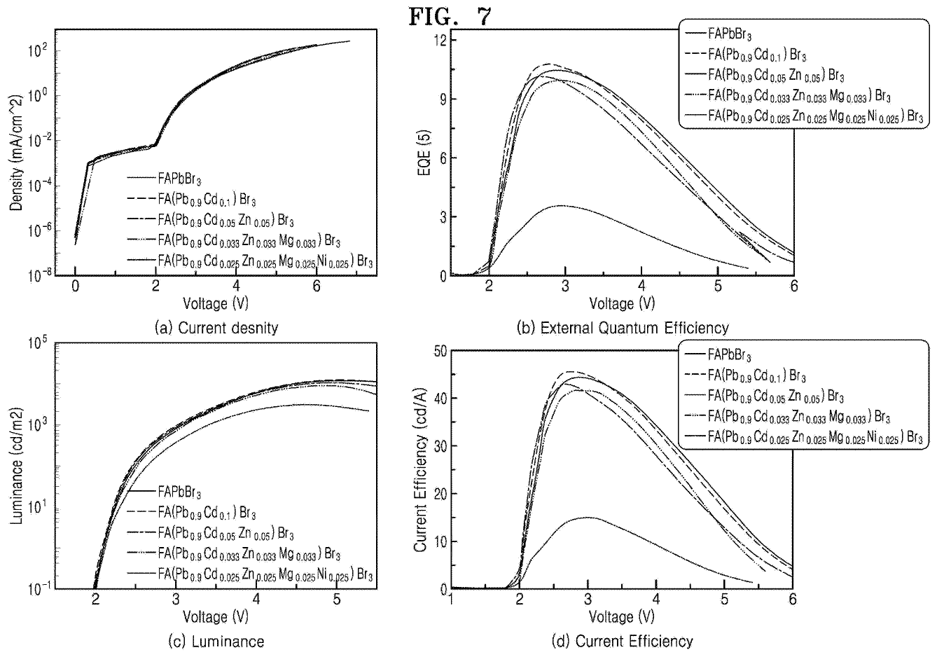

FIG. 7 is a view illustrating performance of a perovskite light-emitting device based on perovskite nanoparticles. Specifically, (a) illustrates current density, (b) illustrates external quantum efficiency, (c) illustrates luminance, and (d) illustrates current efficiency.

Referring to FIG. 7, performance of the perovskite light-emitting device having multi-component perovskite nanoparticles as an emission layer is illustrated. Specifically, a multi-layered light-emitting device having a structure of ITO/PEDOT:PSS/poly-TPD/FAPbBr₃ nanocrystal perovskite/PO-T2T/LiF/Al was fabricated to evaluate current density, efficiency, and luminance performance.

In the light-emitting device, a hole injection sublayer was formed in a thin-film form on an ITO electrode by a solution process, and the hole injection sublayer was formed of PEDOT:PSS to allow current to flow smoothly. A hole transport sublayer was formed of poly-TPD; an emission layer was formed by growing, in a thin-film form, a multi-component perovskite in which multiple materials were incorporated by cation substitution; and an electron transport sublayer and an electron injection sublayer were formed of PO-T2T and LiF, respectively. A cathode was formed by depositing Al to collect current, and the circuit of the device was completed.

Referring to (a), current per unit area as a function of voltage is shown, and current injection efficiency, a turn-on voltage, conductivity, interfacial resistance, and the like may be evaluated therefrom. The cation-substituted light-emitting devices showed a current density pattern similar to that of the conventional device, and the light-emitting devices were confirmed to maintain electrical performance by ensuring stable current flow. Specifically, the slope of the current density curve was not significantly different from that of conventional nanoparticle-based devices, indicating that the charge injection barrier and band alignment are similar; thus, cation substitution does not affect energy levels or bandgap, and performance and efficiency of the device are maintained.

Referring to (b), external quantum efficiency as a function of voltage is shown, and efficiency of the emission layer, specifically, light extraction efficiency and charge recombination efficiency, may be evaluated therefrom. The cation-substituted light-emitting devices, except for FA(Pb_{0.9}Cd_{0.025}Zn_{0.025}Mg_{0.025}Ni_{0.025})Br₃, showed a quantum efficiency pattern similar to that of the conventional device, and the light-emitting devices were confirmed to maintain photoelectric characteristics. Specifically, the maximum EQE value and its position are not significantly different from those of conventional nanoparticle-based devices, indicating that the charge transport process and band alignment are similar; thus, cation substitution does not affect energy levels or bandgap, and performance and efficiency of the device are maintained.

Referring to (c), emission luminance as a function of voltage is shown, and luminance performance, emission uniformity, a turn-on voltage, and the like may be evaluated therefrom. The cation-substituted light-emitting device showed a luminance pattern similar to that of the conventional device, and the light-emitting device was confirmed to stably maintain emission intensity, improving structural and thermal stability while maintaining luminance performance. Specifically, the luminance increase pattern and the saturation voltage are not significantly different from those of conventional nanoparticle-based devices, indicating that light extraction efficiency and the electronic state of the emission centers are similar; thus, cation substitution does not affect the crystal structure or lattice constants, and performance and efficiency of the device are maintained.

Referring to (d), current efficiency as a function of voltage is shown, and energy efficiency, device stability, and the like may be evaluated therefrom. The cation-substituted light-emitting devices, except for FA(Pb_{0.9}Cd_{0.025}Zn_{0.025}Mg_{0.025}Ni_{0.025})Br₃, showed a current efficiency pattern similar to that of the conventional device, and the light-emitting devices were confirmed to maintain optical conversion efficiency. Specifically, the maximum value of the current efficiency was not significantly different from that of conventional nanoparticle-based devices, indicating that charge injection and transport efficiency are similar; thus, cation substitution does not affect lattice constants or the crystal structure, and performance and efficiency of the device are maintained.

The performance of the multi-component perovskite nanoparticles in the emission layer was evaluated in terms of operational efficiency, including current handling capability, efficient light generation, and luminance of the device. Except for the condition in which Ni²⁺ was doped, the cation-substituted light-emitting devices were confirmed to nearly maintain the efficiency of the light-emitting devices based on conventional perovskite nanoparticles. The optical and electrical characteristics of the cation-substituted perovskite nanoparticles may nearly maintain the efficiency of conventional devices, and structural stability and thermal stability may be improved through B-site ion substitution.

Table 4 below shows lifespans of perovskite light-emitting devices.

TABLE 4

| | T₂₀ |
|---|---|
| | (based on luminance |
| Perovskite nanoparticles | of about 100 cd) |
| FAPbBr₃ | 0.646 h |
| FA(Pb_{0.9}Cd_{0.1})Br₃ | 0.800 h |
| FA(Pb_{0.9}Cd_{0.05}Zn_{0.05})Br₃ | 0.448 h |
| FA(Pb_{0.9}Cd_{0.033}Zn_{0.033}Mg_{0.033})Br₃ | 0.345 h |
| FA(Pb_{0.9}Cd_{0.025}Zn_{0.025}Mg_{0.025}Ni_{0.025})Br₃ | 0.386 h |

T₂₀ represents the time taken to reach 80% of initial luminance, and the device lifespan, which indicates stability and durability, may be evaluated therewith. The lifespan of FA(Pb_{0.9}Cd_{0.1})Br₃ was 0.800 h, which was an increase from the FAPbBr₃ lifespan of 0.646 h, confirming that Cd²⁺ may improve lattice stability and charge mobility of the material.

Nanoparticles containing additional doping elements such as Zn²⁺, Mg²⁺, and Ni²⁺ showed a trend of decreasing lifespan to 0.448 h, 0.345 h, and 0.386 h, which indicates that the added elements affected charge mobility or optical characteristics. Specifically, interactions between the multi-component doping elements may destabilize the lattice structure or hinder electron movement, and thus, charge mobility may be lowered, thereby shortening the lifespan. In addition, changes in optical characteristics, such as lowered emission efficiency or decreased photoluminescence intensity, may be induced by interfering with an optical transition or a recombination process.

Cd²⁺ may affect the lattice structure or energy levels while substituting for a portion of Pb²⁺. Cd²⁺ doping may improve nanoparticle stability, thereby increasing crystal structure stability, and the lifespan of the light-emitting device may be extended.

Through cation substitution, various metal cations may be introduced into the B-site, and multi-component perovskite nanoparticles may improve structural stability by increasing the configurational entropy of the system, thereby lowering the total free energy. By controlling the composition of multiple B-site elements, lattice distortion may be suppressed, and a light-emitting device with increased thermodynamic stability and thermal decomposition resistance may be realized, thereby enabling the manufacture of a device capable of stable operation without performance degradation even in a high-temperature environment.

According to embodiments of the present disclosure, by substituting B-site cations of a perovskite compound, emission efficiency, thermal stability, and chemical stability of a light-emitting material and a light-emitting device may be improved.

As described above, the present disclosure has been described with reference to the embodiments illustrated in the drawings, but this is merely exemplary, and those of ordinary skill in the art will understand that various modifications and other equivalent embodiments are possible therefrom. Therefore, the true technical scope of protection of the present disclosure should be defined by the technical spirit of the appended claims.

Specific implementations described in the embodiments are merely illustrative and do not limit the scope of the embodiments in any way. Furthermore, unless specifically stated as “essential,” “critical,” or the like, an element may not necessarily be required for application of the present disclosure.

In the specification of the embodiments (particularly in the claims), the use of the term “said” and similar referential terms may refer to both singular and plural. Furthermore, where a range is recited in the embodiments, the invention includes application of individual values falling within the range (unless there is a statement to the contrary), as if each individual value constituting the range were recited in the detailed description. Lastly, unless a specific order is explicitly recited or there is a statement to the contrary, the steps constituting a method according to the embodiments may be performed in any suitable order. The embodiments are not necessarily limited by the order in which the steps are recited. The use of all examples or exemplary terms (e.g., etc.) in the embodiments is merely intended to describe the embodiments in detail, and the scope of the embodiments is not limited by such examples or exemplary terms unless limited by the claims. Furthermore, those of ordinary skill in the art will appreciate that various modifications, combinations, and changes may be made in accordance with design conditions and factors within the scope of the appended claims or equivalents thereof.

What is claimed is:

1. A perovskite compound represented by Formula 1: 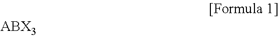
wherein, in Formula 1,
A is an inorganic or organic cation,
B comprises a first ion and one or more metal cations substituting for the first ion, and
X is a halogen element.

2. The perovskite compound of claim 1,
wherein A is FA, FA(CH(NH₂)₂), MA(CH₃NH₃), or Cs.

3. The perovskite compound of claim 1,
wherein X is I, Br, or Cl.

4. The perovskite compound of claim 1,
wherein the first ion is Pb, and
B is represented by Formula 2: 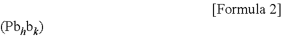
wherein b is an element selected from the group consisting of Cd, Zn, Mg, Ni, Sr, Sn, Ca, Mn, and Ge, and
h+k=1.

5. The perovskite compound of claim 1,
wherein the first ion is Pb, and
B is represented by Formula 3: 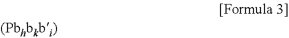
wherein each of b and b′ is an element selected from the group consisting of Cd, Zn, Mg, Ni, Sr, Sn, Ca, Mn, and Ge, and
h+k+i=1.

6. The perovskite compound of claim 1,
wherein the first ion is Pb, and
B is represented by Formula 4: 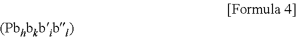
wherein each of b, b′, and b″ is an element selected from the group consisting of Cd, Zn, Mg, Ni, Sr, Sn, Ca, Mn, and Ge, and
h+k+i+I=1.

7. The perovskite compound of claim 1,
wherein A is represented by Formula 5: 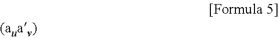
wherein each of a and a′ is selected from the group consisting of FA, FA(CH(NH₂)₂), MA(CH₃NH₃), or Cs, and
u+v=1.

8. The perovskite compound of claim 1,
wherein A is represented by Formula 6: 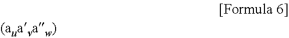
wherein each of a, a′, and a″ is selected from the group consisting of FA, FA(CH(NH₂)₂), MA(CH₃NH₃), or Cs, and
u+v+w=1.

9. The perovskite compound of claim 1,
wherein X is represented by Formula 7: 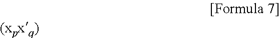
wherein each of x and x′ is selected from the group consisting of I, Br, and Cl, and
p+q=3.

10. The perovskite compound of claim 1,
wherein X is represented by Formula 8: 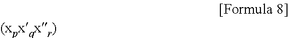
wherein each of x, x′, and x″ is selected from the group consisting of I, Br, and Cl, and
p+q+r=3.

11. A light-emitting device comprising:
a substrate;
a hole transport layer on the substrate;
an emission layer on the hole transport layer;
an electron transport layer on the emission layer; and
a cathode on the electron transport layer,
wherein the emission layer comprises the perovskite compound according to claim 1.
